(19) United States
(12) Patent Application Publication
(10) Pub. No.: US 2019/0222230 A1
(43) Pub. Date: Jul. 18, 2019

(54) SYSTEMS AND METHODS FOR AN EFFICIENTLY ROUTABLE LOW-DENSITY PARITY-CHECK (LDPC) DECODER

(71) Applicant: Avago Technologies International Sales Pte. Limited, Singapore (SG)

(72) Inventor: Maged F. Barsoum, San Jose, CA (US)

(73) Assignee: Avago Technologies International Sales Pte. Limited, Singapore (SG)

(21) Appl. No.: 16/251,631

(22) Filed: Jan. 18, 2019

Related U.S. Application Data
(60) Provisional application No. 62/618,954, filed on Jan. 18, 2018.

(51) Int. Cl. H03M 13/11

(52) U.S. Cl. CPC H03M 13/1174; H03M 13/1105; H03M 13/1157

(57) ABSTRACT

A decoder system can include a plurality of smaller sub-decoders such that the decoder system is a partitioned LDPC decoder system. Each sub-decoder may be communicably coupled to two adjacent sub-decoders. Each sub-decoder in the partitioned LDPC decoder system may be responsible for decoding an exclusive subset of a code word based on information received from two adjacent sub-decoders. Each sub-decoder may be one of two or more types.

### CROSS-REFERENCE TO RELATED APPLICATION

Related application U.S. application Ser. No. 14/067,198 is herein incorporated by reference in its entirety. This application claims benefit of provisional application 62/618,954, filed on Jan. 18, 2018.

### BACKGROUND

The “background” description provided herein is for the purpose of generally presenting the context of the disclosure. Work of the presently named inventors, to the extent it is described in this background section, as well as aspects of the description which may not otherwise qualify as prior art at the time of filing, are neither expressly or impliedly admitted as prior art against the present invention.

LDPC code is a linear error correcting code, which is a method of transmitting a message on a noisy transmission channel. An LDPC decoder can be configured to decode LDPC codes. However, it is may not practical to implement integrated circuit LDPC decoders running at high speed for LDPC codes with a large codeword size because of routing congestion and the resulting place and route issues. The place and route issues can result in very low utilization, which can make the implementation impractical due to the large die size and higher power.

### SUMMARY

The foregoing paragraphs have been provided by way of general introduction, and are not intended to limit the scope of the following claims. The described embodiments, together with further advantages, will be best understood by reference to the following detailed description taken in conjunction with the accompanying drawings.

According to embodiments of the disclosed subject matter, a decoder system can include a plurality of smaller sub-decoders such that the decoder system is a partitioned LDPC decoder system. Each sub-decoder in the partitioned LDPC decoder system is responsible for decoding an exclusive subset of a code word based on information received from two adjacent sub-decoders. Additionally, each sub-decoder is communicably coupled to two adjacent sub-decoders. Each sub-decoder may be one of two or more types. As a result, the processing for each check node is performed in two adjacent sub-decoders since each check node is split in two adjacent sub-decoders.

### BRIEF DESCRIPTION OF THE DRAWINGS

A more complete appreciation of the disclosure and many of the attendant advantages thereof will be readily obtained as the same becomes better understood by reference to the following detailed description when considered in connection with the accompanying drawings, wherein:

FIG. 1 depicts an exemplary communication system according to one or more aspects of the disclosed subject matter;

FIG. 2 depicts an exemplary communication system according to one or more aspects of the disclosed subject matter;

FIG. 3 illustrates an exemplary apparatus operable to perform LDPC decoding processing and/or LDPC code construction according to one or more aspects of the disclosed subject matter;

FIG. 4 depicts an exemplary LDPC decoder according to one or more aspects of the present disclosure;

FIG. 5A depicts a crossover graph as a measure of routing congestion according to one or more aspects of the present disclosure;

FIG. 5B depicts a crossover graph as a measure of routing congestion according to one or more aspects of the present disclosure;

FIG. 6 depicts an exemplary LDPC decoder system according to one or more aspects of the disclosed subject matter;

FIG. 7 depicts an exemplary partitioned LDPC decoder system according to one or more aspects of the disclosed subject matter;

FIG. 8 depicts an exemplary sub-decoder implementation according to one or more aspects of the disclosed subject matter.

FIG. 9 illustrates a number of example parity check matrices (H) that may be employed in an embodiment; and

FIGS. 10A and 10B illustrate how a check node (check processor) may be split between two adjacent sub-decoders.

### DETAILED DESCRIPTION

The description set forth below in connection with the appended drawings is intended as a description of various embodiments of the disclosed subject matter and is not necessarily intended to represent the only embodiment(s). In certain instances, the description includes specific details for the purpose of providing an understanding of the disclosed subject matter. However, it will be apparent to those skilled in the art that embodiments may be practiced without these specific details. In some instances, well-known structures and components may be shown in block diagram form in order to avoid obscuring the concepts of the disclosed subject matter.

Reference throughout the specification to “one embodiment” or “an embodiment” means that a particular feature, structure, characteristic, operation, or function described in connection with an embodiment is included in at least one embodiment of the disclosed subject matter. Thus, any appearance of the phrases “in one embodiment” or “in an embodiment” in the specification is not necessarily referring to the same embodiment. Further, the particular features, structures, characteristics, operations, or functions may be combined in any suitable manner in one or more embodiments. Further, it is intended that embodiments of the disclosed subject matter can and do cover modifications and variations of the described embodiments.

It must be noted that, as used in the specification and the appended claims, the singular forms “a,” “an,” and “the” include plural referents unless the context clearly dictates otherwise. That is, unless clearly specified otherwise, as used herein the words “a” and “an” and the like carry the meaning of “one or more.” Additionally, it is to be understood that terms such as “left,” “right,” “top,” “bottom,” “front,” “rear,” “side,” “height,” “length,” “width,” “upper,” “lower,” “interior,” “exterior,” “inner,” “outer,” and the like that may be used herein, merely describe points of reference and do not necessarily limit embodiments of the disclosed subject matter to any particular orientation or configuration. Furthermore, terms such as “first,” “second,” “third,” etc., merely identify one of a number of portions, components, points of reference, operations and/or functions as described herein, and likewise do not necessarily limit embodiments of the disclosed subject matter to any particular configuration or orientation.

Referring now to the drawings, wherein like reference numerals designate identical or corresponding parts throughout the several views.

Generally speaking, within the context of communication systems that employ LDPC codes, there is a first communication device at one end of a communication channel with encoder capability and second communication device at the other end of the communication channel with decoder capability. In many instances, one or both of these two communication devices includes encoder and decoder capability (e.g., within a bi-directional communication system). LDPC codes can be applied in a variety of additional applications as well, including those that employ some form of data storage (e.g., hard disk drive (HDD) applications and other memory storage devices) in which data is encoded before writing to the storage media, and then the data is decoded after being read/retrieved from the storage media.

Communication systems have been around for some time, and their presence into modern life is virtually ubiquitous (e.g., television communication systems, telecommunication systems including wired and wireless communication systems, etc.). As these communication systems continue to be developed, there is an ever present need for designing various means by which information may be encoded for transmitting from a first location to a second location. In accordance with this, error correction codes (ECCs) are a critical component in ensuring that the information received at the second location is actually the information sent from the first location. LDPC (Low Density Parity Check) codes are one such type of ECC that can be employed within any of a variety of communication systems.

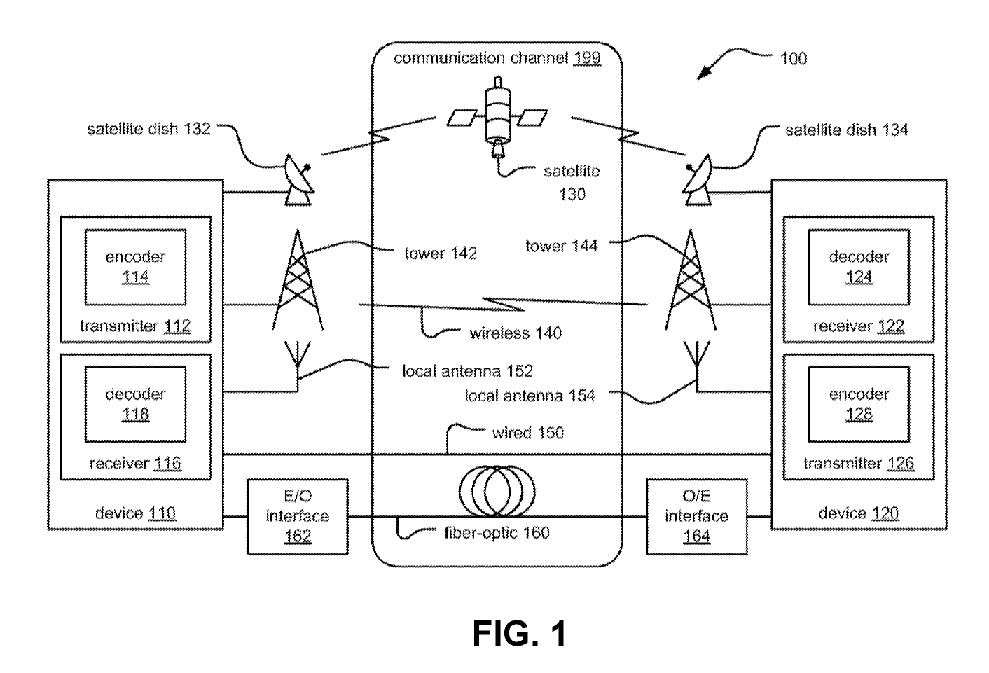

The goal of digital communications systems is to transmit digital data from one location, or subsystem, to another either error free or with an acceptably low error rate. As shown in FIG. 1, data may be transmitted over a variety of communications channels in a wide variety of communication systems: magnetic media, wired, wireless, fiber, copper, and other types of media as well.

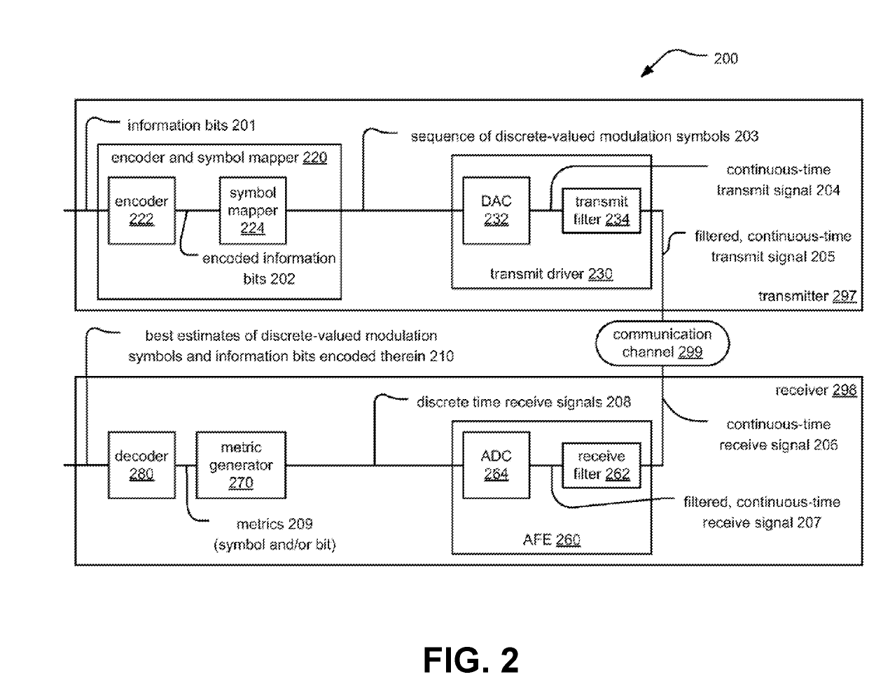

FIG. 1 and FIG. 2 illustrate various embodiments of communication systems, 100 and 200, respectively.

Referring to FIG. 1, this embodiment of a communication system 100 is a communication channel 199 that communicatively couples a communication device 110 (including a transmitter 112 having an encoder 114 and including a receiver 116 having a decoder 118) situated at one end of the communication channel 199 to another communication device 120 (including a transmitter 126 having an encoder 128 and including a receiver 122 having a decoder 124) at the other end of the communication channel 199. In some embodiments, either of the communication devices 110 and 120 may only include a transmitter or a receiver. There are several different types of media by which the communication channel 199 may be implemented (e.g., a satellite communication channel 130 using satellite dishes 132 and 134, a wireless communication channel 140 using towers 142 and 144 and/or local antennae 152 and 154, a wired communication channel 150, and/or a fiber-optic communication channel 160 using electrical to optical (E/O) interface 162 and optical to electrical (O/E) interface 164)). In addition, more than one type of media may be implemented and interfaced together thereby forming the communication channel 199.

To reduce transmission errors that may undesirably be incurred within a communication system, error correction and channel coding schemes are often employed. Generally, these error correction and channel coding schemes involve the use of an encoder at the transmitter and a decoder at the receiver.

Any of the various types of LDPC codes described herein can be employed within any such desired communication system (e.g., including those variations described with respect to FIG. 1), any information storage device (e.g., hard disk drives (HDDs), network information storage devices and/or servers, etc.) or any application in which information encoding and/or decoding is desired.

Referring to the communication system 200 of FIG. 2, at a transmitting end of a communication channel 299, information bits 201 are provided to a transmitter 297 that is operable to perform encoding of these information bits 201 using an encoder and symbol mapper 220 (which may be viewed as being distinct functional blocks 222 and 224, respectively) thereby generating a sequence of discrete-valued modulation symbols 203 that is provided to a transmit driver 230 that uses a DAC (Digital to Analog Converter) 232 to generate a continuous-time transmit signal 204 and a transmit filter 234 to generate a filtered, continuous-time transmit signal 205 that substantially comports with the communication channel 299. At a receiving end of the communication channel 299, continuous-time receive signal 206 is provided to an AFE (Analog Front End) 260 that includes a receive filter 262 (that generates a filtered, continuous-time receive signal 207) and an ADC (Analog to Digital Converter) 264 (that generates discrete-time receive signals 208). A metric generator 270 calculates metrics 209 (e.g., on either a symbol and/or bit basis) that are employed by a decoder 280 to make best estimates of the discrete-valued modulation symbols and information bits encoded therein 210.

The decoders of either of the previous embodiments may be implemented to include various aspects and/or embodiment of the disclosed subject matter. In addition, several of the following figures describe other and particular embodiments (some in more detail) that may be used to support the devices, systems, functionality and/or methods that may be implemented in accordance with certain aspects and/or embodiments of the invention. One particular type of signal that is processed according to certain aspects and/or embodiments of the invention is an LDPC coded signal.

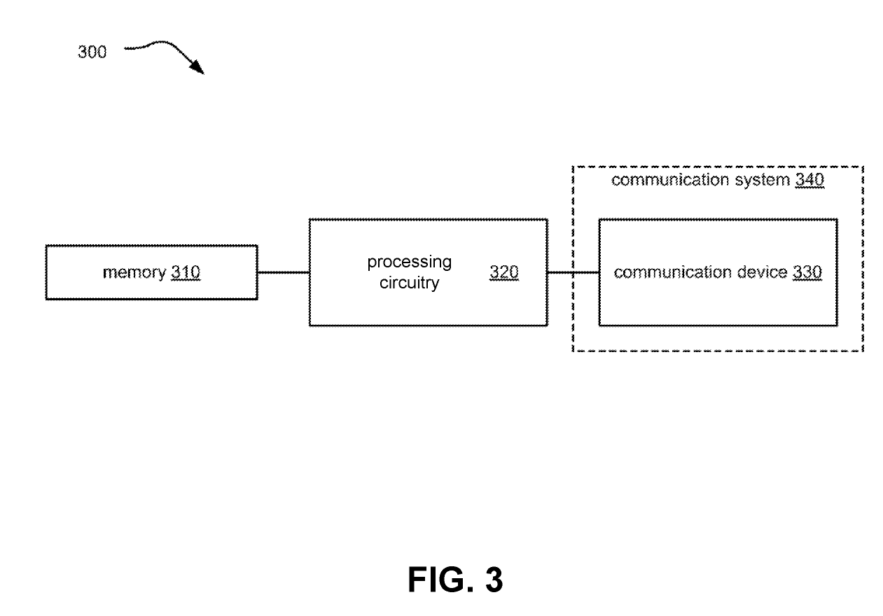

FIG. 3 illustrates an embodiment of an apparatus 300 that is operable to perform LDPC decoding processing and LDPC encoding processing and/or LDPC code construction. The apparatus 300 includes a processing circuitry 320, and a memory 310. The memory 310 is coupled to the processing circuitry 320, and the memory 310 is operable to store operational instructions that enable the processing circuitry 320 to perform a variety of functions. The processing circuitry 320 is operable to perform and/or direct the manner in which various LDPC codes may be constructed in accordance with any embodiment described herein, or any equivalent thereof.

The processing circuitry 320 can be implemented using a shared processing device, individual processing devices, or a plurality of processing devices. Such a processing device may be a microprocessor, micro-controller, digital signal processor, microcomputer, central processing unit, field programmable gate array, programmable logic device, state machine, logic circuitry, analog circuitry, digital circuitry, and/or any device that manipulates signals (analog and/or digital) based on operational instructions. The memory 310 may be a single memory device or a plurality of memory devices. Such a memory device may be a read-only memory, random access memory, volatile memory, non-volatile memory, static memory, dynamic memory, flash memory, and/or any device that stores digital information. Note that when the processing circuitry 320 implements one or more of its functions via a state machine, analog circuitry, digital circuitry, and/or logic circuitry, the memory storing the corresponding operational instructions is embedded with the circuitry comprising the state machine, analog circuitry, digital circuitry, and/or logic circuitry.

If desired in some embodiments, the manner in which LDPC code construction is to be performed (e.g., the LDPC parity matrix (H) of a corresponding LDPC code, the submatrices within the LDPC parity matrix, etc.) can be provided from the apparatus 300 to a communication system 340 that is operable to employ and perform LDPC encoding and/or decoding using a desired LDPC code. For example, information corresponding to the LDPC code being used (e.g., the parity check matrix of the LDPC code) can also be provided from the processing circuitry 320 to any of a variety of communication devices 330 implemented within any desired such communication system 340 as well.

If desired, the apparatus 300 can be designed to generate multiple means of constructing LDPC codes in accordance with multiple needs and/or desires as well. In some embodiments, the processing circuitry 320 can selectively provide different information (e.g., corresponding to different LDPC codes and their corresponding LDPC parity matrices, relative performance comparison between the various LDPC codes, etc.) to different communication devices and/or communication systems. That way, different communication links between different communication devices can employ different LDPC codes and/or means by which to perform LDPC encoding and/or decoding. Clearly, the processing circuitry 320 can also provide the same information to each of different communication devices and/or communication systems as well without departing from the scope and spirit of the disclosed subject matter.

An LDPC code may be viewed as being a code having a binary parity check matrix H such that nearly all of the elements of the matrix have values of zeroes (e.g., the binary parity check matrix H is sparse). For example, H=(h_{i,j})_{m×n} may be viewed as being a parity check matrix of an LDPC code with block length n (number of symbols or bits in each codeword), of which m symbols are parity symbols as shown here:

$$H = [ \begin{matrix}{h}_{0 , 0} & ⋯ & {h}_{0 , n - 1} \\ ⋮ & ⋱ & ⋮ \\ {h}_{m - 1 , 0} & ⋯ & {h}_{m - 1 , n - 1}\end{matrix} ]$$

Each row of H may correspond to a parity check equation where an element h_{i,j} indicates whether the associated data symbol participates in a particular parity check (a ‘set’ or ‘1’ element indicates participation, and a ‘clear’ or ‘0’ indicates no participation).

The row and column weights are defined as the number of set elements in a given row or column of H, respectively. The set elements of H are chosen to satisfy the performance requirements of the code and may also be configured, in some embodiments, to enable a particular decoder structure. The number of set elements in the j-th column of the parity check matrix, H, may be denoted as dᵥ(j), and the number of set elements in the i-th row of the parity check matrix may be denoted as d_{c}(i). If dᵥ(j)=dᵥ for all j, and d_{c}(i)=d_{c} for all i, then the LDPC code is called a (dᵥ, d_{c}) regular LDPC code (or simply as a regular LDPC code), otherwise the LDPC code is referred to as an irregular LDPC code.

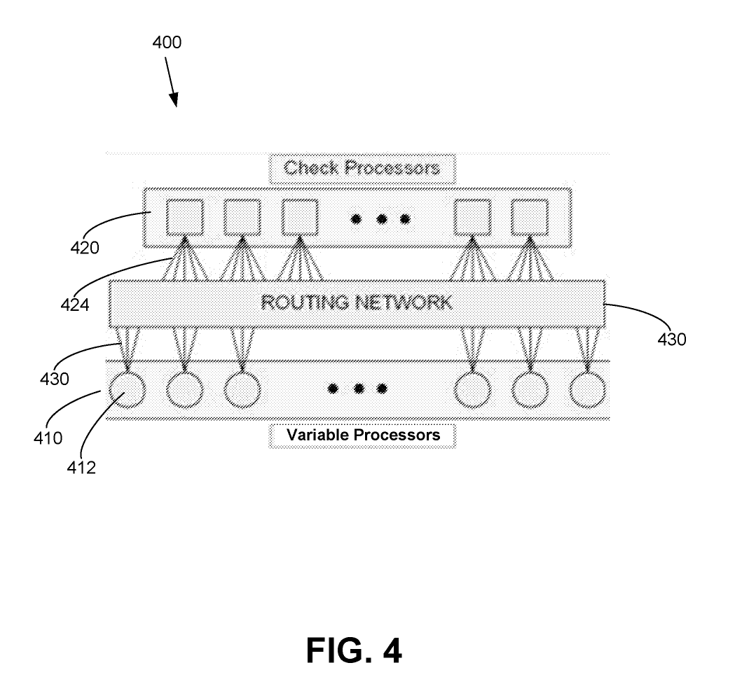

FIG. 4 depicts an exemplary LDPC decoder according to one or more aspects of the present disclosure. An LDPC code can be represented as a bipartite graph 400 (sometimes referred to as a Tanner graph) based on its parity check matrix, with lower nodes representing variable nodes (or bit nodes) 410 in a bit decoding approach to decoding LDPC coded signals, and the upper nodes representing check nodes 420. The bipartite graph 400 of the LDPC code defined by H may be defined by n variable nodes 410 and m check nodes 420. Every variable node of the n variable nodes 410 has exactly dᵥ(j) edges (an example edge shown using reference numeral 430) connecting the variable node 412, to one or more of the check nodes 420. Analogously, every check node of the m check nodes 420 has exactly d_{c}(i) edges (one being shown as reference numeral 424) connecting this node to one or more of the variable nodes 410. In some embodiments, one or more variable nodes 410 may be implemented by circuitry or as a processor (a variable processor), and one or more check nodes 420 may be also be implemented by circuitry or as a processor (a check processor). In some embodiments, the edges connecting variable nodes 410 and the edges connecting check nodes 420 may be connected through a routing network 440.

A typical problem with routing network 440 is that a bus of n lines needs to be delivered in one of p different permutations (i.e., orders). A permuting switch with n lines and p permutations can be denoted as a permute (n, p), or an n×p permuter. Ideally, it would be desirable for the area of the routing network 430 to grow linearly with “n”.

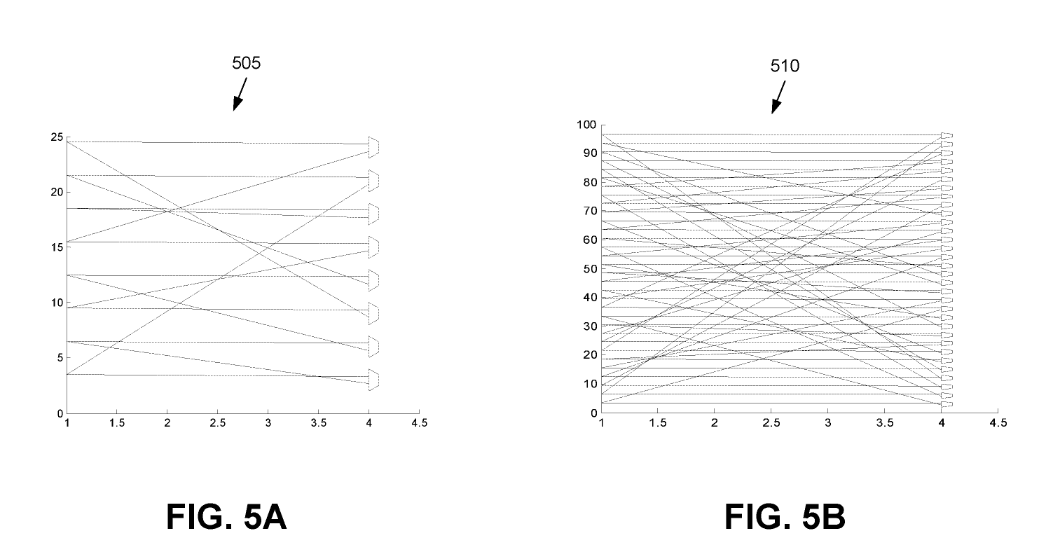

FIG. 5A and FIG. 5B depict crossovers in a routing network (such as routing network 440 in FIG. 4) as a measure of routing congestion. For example, in FIG. 5A graph 505 depicts crossovers when n=8 and p=2. There are 34 intersections in graph 505. In FIG. 5B, graph 510 depicts crossovers when n=32 and p=2. There are 638 intersections in graph 510. As can be seen, the number of intersections grows much faster than n.

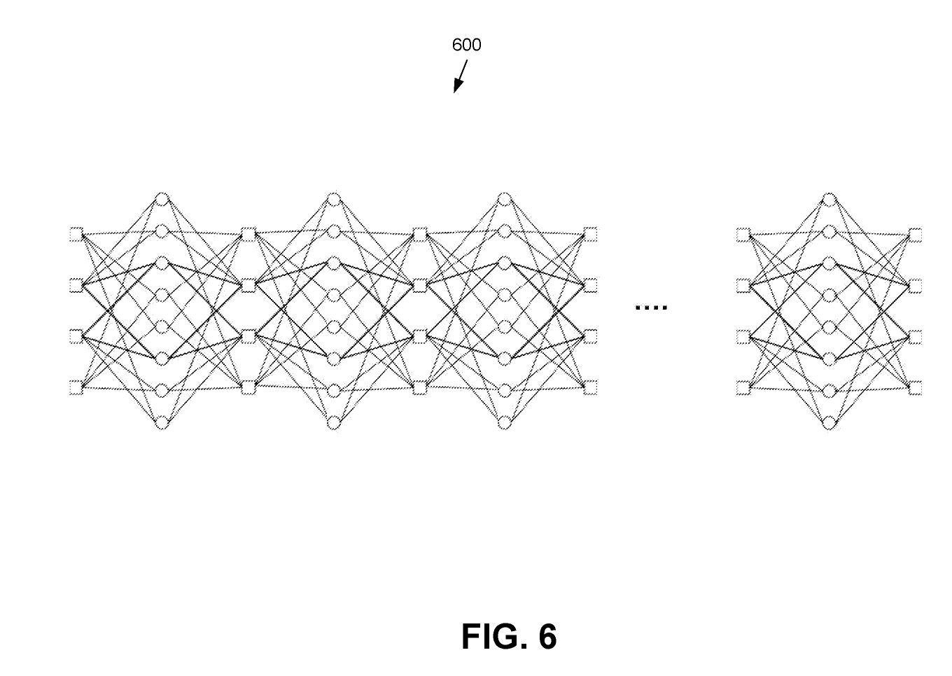

FIG. 6 depicts an exemplary LDPC decoder system 600 according to one or more embodiments of the present disclosure. In FIG. 6, the decoder represented by bipartite graph 400 (FIG. 4) has been partitioned into a chained arrangement of smaller decoders connected together in a particular order.

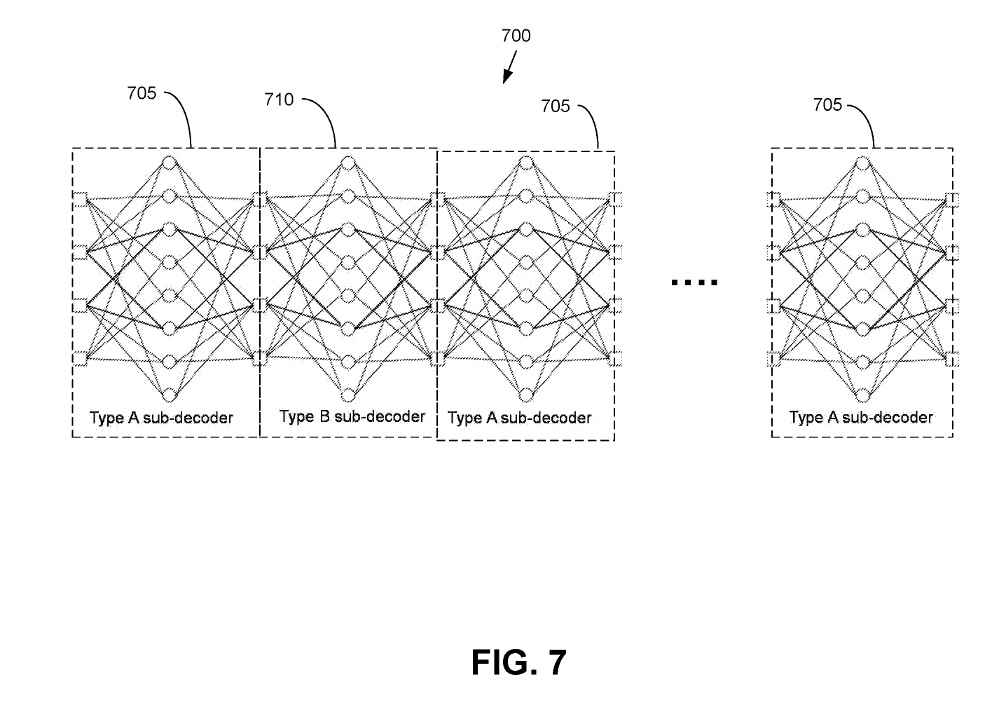

FIG. 7 depicts an exemplary partitioned LDPC decoder system 700 according to one or more aspects of the present disclosure. The partitioned LDPC decoder system 700 can include one or more type A sub-decoders 705 and one or more type B sub-decoders 710.

The partitioned LDPC decoder system 700 can be implemented efficiently for a class of LDPC codes with very large code word size. The decoder is constructed using a chained arrangement of smaller (possibly much smaller) sub-decoders. Each type A sub-decoder 705 and type B sub-decoder 710 may be communicably coupled to two adjacent sub-decoders. The processing for each check node may be performed in two adjacent sub-decoders (i.e., each check node may be split in two adjacent sub-decoders). In one embodiment, each sub-decoder may be one of two types: type A sub-decoder 704 and type B sub-decoder 710. Each interior (an interior sub-decoder is any sub-decoder that is not the first or last in a chain) type A sub-decoder 705 is connected to two type B sub-decoders 710. Similarly, each interior type B sub-decoder 710 is connected to two type A sub-decoders 705. As a result, the partitioned LDPC decoder system 700 can be composed of a chained sequence of A-B-A-B . . . A-B-A (an odd number of sub-decoders) or A-B-A-B . . . A-B (an even number of sub-decoders), for example. In some embodiments, the first and last sub-decoders in a chain may also be connected to each other to form a ring. In other embodiments, the first and last sub-decoders may not be connected to each another.

In some embodiments, the type A sub-decoder 705 and the type B sub-decoder 710 include the same number of variable nodes, and the number of variable nodes in each sub-decoder is equal to the size of the codeword (n) divided by the total number of sub-decoders in the partitioned LDPC decoder system 700. For example, if the codeword size is 99990, and the LDPC decoder is partitioned into 15 sub-decoders (eight type A sub-decoders and 7 type B sub-decoders), then each sub-decoder would have 99990/15 or 6666 variable nodes.

For decoding an LDPC codeword, each sub-decoder in partitioned LDPC decoder system 700 is responsible for decoding an exclusive subset of the codeword, with the help of information it receives from two adjacent sub-decoders.

While FIG. 7 depicts a partitioned LDPC decoder system 700 as having only two types of sub-decoders, other embodiments of a partitioned LDPC decoder system may use more than two types of sub-decoders. In an embodiment, two or more types of sub-decoders may be arranged in an ordered chained sequence. For example, a partitioned LDPC decoder system with five types of sub-decoders (A, B, C, D, and E) may be arranged as A-B-C-D-E-C-B-A-E-D . . . A-B-C-D-E. A similar ordered chained sequence may be constructed for any number of types of sub-decoders greater than one. Constructing the partitioned LDPC decoder system 700 using only two types of sub-decoders may simplify the design significantly. For example, only two sub-decoders need to be designed and implemented (placed and routed) and copies of each can be replicated and connected together as described herein. Additionally, because each sub-decoder in partitioned LDPC decoder system 700 communicates with only two adjacent sub-decoders, routing congestion may be significantly reduced.

Further, in some embodiments, all of the type A sub-decoders 705 and type B sub-decoders 710 may start decoding at the same time. In other embodiments, a predetermined number of the type A sub-decoders 705 and type B sub-decoders 710 may start later than others according to a predetermined decoding schedule that optimizes performance and/or power.

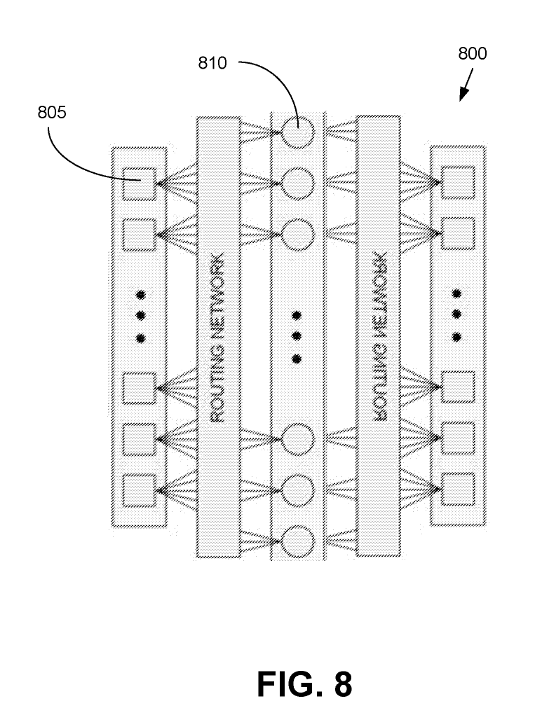

FIG. 8 depicts an exemplary sub-decoder implementation 800 according to one or more aspects of the disclosed subject matter. In an exemplary implementation of the sub-decoder, each check processor 805 can process several check nodes one at a time via multiplexing, and likewise the variable processors 810.

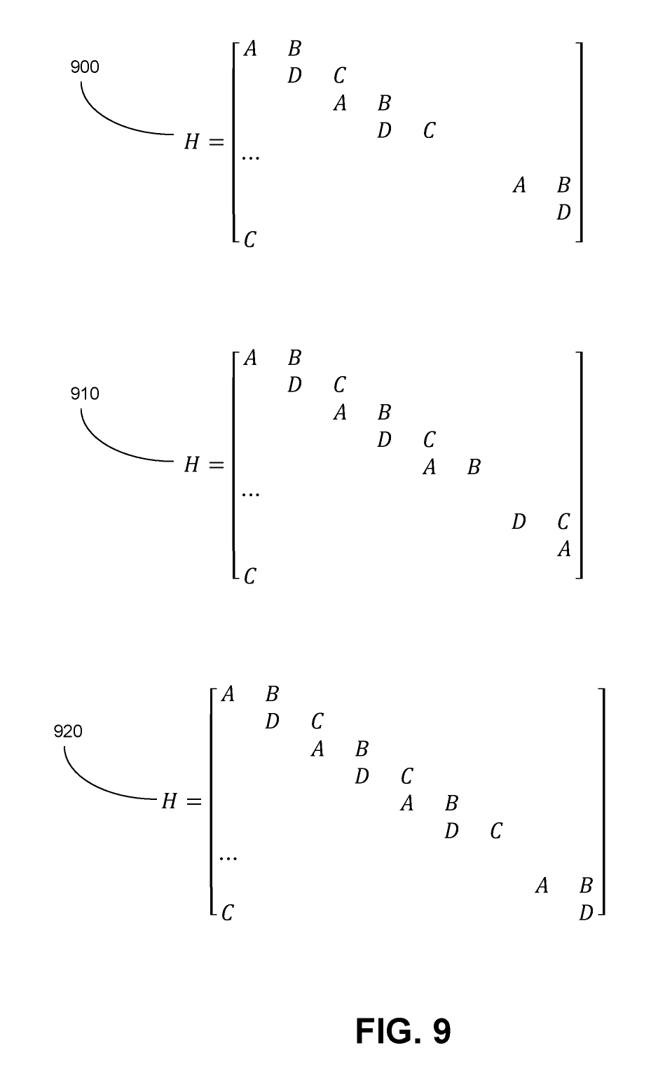

FIG. 9 illustrates a number of example parity check matrices (H) that may be employed, in an embodiment, to enable the use of the partitioned LDPC decoder system 700 illustrated in FIG. 7. Many other forms of the parity check matrix H that may also facilitate the use of the disclosed partitioned LDPC decoder system 700. In each of the examples shown in FIG. 9, the parity check matrix H is illustrated as a matrix of submatrices. For example, in the first form 900, the parity check matrix H has two submatrices (A, B) in the first row, in the first two columns. Similarly, the second row has two submatrices (D, C) in the second and third columns. In all of the examples, the labeled submatrices are sparse regular submatrices and the blank matrix elements are all zeros.

In a partitioned LDPC decoder based on the first form 900 and the second form 910, the first sub-decoder and last sub-decoder are not connected, whereas in a partitioned LDPC decoder based on the third form 920, the first sub-decoder and the last sub-decoder are connected. Further, a partitioned LDPC decoder based on the first form 900 and the third form 920 has an even number of sub-decoders, while a partitioned LDPC decoder based on the second form 910 has an odd number of sub-decoders. Finally, the third form 920 is a regular LDPC code, whereas the first form 900 and the second form 910 are irregular LDPC codes because some of the check nodes in the first and last sub-decoders have a smaller degree.

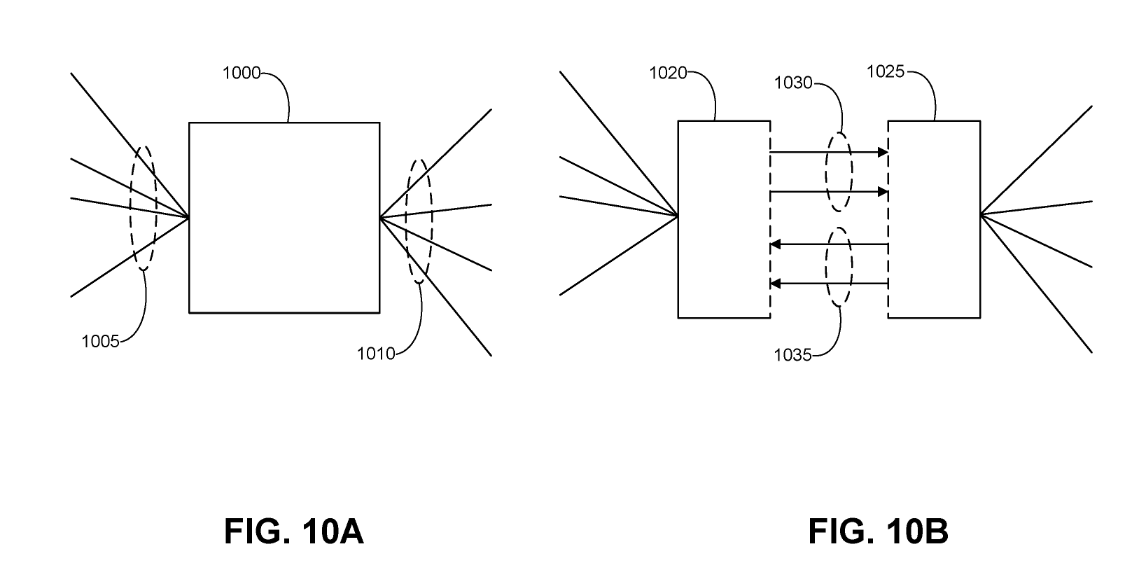

FIGS. 10A and 10B illustrate how a check node (check processor) may be split between two adjacent sub-decoders to minimize the amount of information to be communicated between the two sub-decoders. This facilitates designing the internal place and route of one type of sub-decoder (e.g. subdecoder type A), to be used repeatedly for constructing the full decoder, while minimizing the number of connections each sub-decoder will have with a neighboring sub-decoder. Referring to FIG. 10A, check node 1000 may be connected to variable nodes (not shown) of a first sub-decoder through a first set of edges 1005 and to variable nodes (not shown) of a second sub-decoder through a second set of edges 1010. FIG. 10B illustrates the splitting of check node 1000 (FIG. 10A) into left-half check node 1020 and right-half check node 1025.

For example, the messages 1030 from left-half check node 1020 to right-half check node 1025, and the messages 1035 from right-half check node 1025 to left-half check node 1020 can include the minimum of the absolute value of the variable node to check node messages in one sub-decoder that all go to the same check node. The information can also include the XOR of the sign bits of these variable nodes to check node messages. Further, the information can include partial parity check bits (i.e., since each check node is split between two adjacent sub-decoders, each parity check bit is the XOR of some bits in one sub-decoder and some other bits in an adjacent sub-decoder). A partial parity bit is the XOR of the codeword bits as decoded so far in one sub-decoder belonging to the same check node.

To check the syndrome, each sub-decoder may use partial parity check bits from the adjacent sub-decoder. Each half check node updates the check to variable node messages based on the variable to check node messages it received, and the information it received from the other half check node. The partial check bit from a left half check node and the corresponding right half check node may be XORed to determine whether the logical constraint corresponding to that check node has been met or not.

When one sub-decoder converges, it can be turned off after it sends the information it needs to send to the two adjacent decoders. This information can be limited to the partial parity check bits, for example.

It should be appreciated that the type of information shared between adjacent sub-decoders as described above is exemplary and could include additional or different information depending on the application, for example.

The partitioned LDPC decoder system 700 can include various advantages. Prior solutions including implementation of LDPC decoders for large code word size running at high speed have typically been avoided and deemed unpractical. Instead, other types of error correction codes have been used (e.g., concatenated codes), which provide worse performance and/or require higher power, larger die area, or longer latency. The partitioned LDPC decoder system 700 allows for very powerful LDPC codes with large code word size, delivering high net coding gain, very low error floor, at a smaller power, smaller die size, and smaller latency.

Having now described embodiments of the disclosed subject matter, it should be apparent to those skilled in the art that the foregoing is merely illustrative and not limiting, having been presented by way of example only. Thus, although particular configurations have been discussed herein, other configurations can also be employed. Numerous modifications and other embodiments (e.g., combinations, rearrangements, etc.) are enabled by the present disclosure and are within the scope of one of ordinary skill in the art and are contemplated as falling within the scope of the disclosed subject matter and any equivalents thereto. Features of the disclosed embodiments can be combined, rearranged, omitted, etc., within the scope of the invention to produce additional embodiments. Furthermore, certain features may sometimes be used to advantage without a corresponding use of other features. Accordingly, Applicant(s) intend(s) to embrace all such alternatives, modifications, equivalents, and variations that are within the spirit and scope of the disclosed subject matter.

1. A low-density parity-check (LDPC) decoder, comprising:
circuitry configured as a regular ordered chain of sub-decoders, wherein each of the sub-decoders is one of two or more types and each interior sub-decoder is between and communicably coupled to each of two adjacent sub-decoders and each of the two adjacent sub-decoders are of a type different from the type of the sub-decoder between them, and
wherein the circuitry of each sub-decoder is configured to decode an exclusive subset of a codeword based on information received from the one or two adjacent sub-decoders.

2. The LDPC decoder of claim 1, wherein a first and last sub-decoder are communicably coupled to each other.

3. The LDPC decoder of claim 1, wherein a number of bits decoded by the circuitry of each sub-decoder is equal to a size of the codeword divided by a total number of sub-decoders.

4. The LDPC decoder of claim 1, wherein the circuitry of all sub-decoders can begin decoding simultaneously.

5. The LDPC decoder of claim 1, wherein the circuitry of one or more sub-decoders can begin decoding later than other sub-decoders.

6. The LDPC decoder of claim 1, wherein the sub-decoders are of two types.

7. The LDPC decoder of claim 1, wherein the circuitry of each of the sub-decoders is further configured to exchange partial parity check bits with the two adjacent sub-decoders.

8. The LDPC decoder of claim 1, wherein the circuitry of each of the sub-decoders comprises a plurality of variable nodes and a plurality of check nodes and is further configured to exchange a minimum of an absolute value of variable node to check node messages in one sub-decoder that all go to a same check node.

9. An apparatus comprising:
a memory;
processing circuitry coupled to the memory;
a communication device coupled to the processing circuitry;
wherein the memory, processing circuitry and communication device are configured to form a low-density parity-check (LDPC) decoder comprising:
an ordered chain of sub-decoders, wherein each of the sub-decoders is one of two types and each interior sub-decoder is between and communicably coupled to each of two adjacent sub-decoders and each of the two adjacent sub-decoders are of a type different from the type of the sub-decoder between them, and
wherein each sub-decoder is configured to decode an exclusive subset of a codeword based on information received from the two adjacent sub-decoders.

10. The apparatus of claim 9, wherein a first and last sub-decoder are communicably coupled to each another.

11. The apparatus of claim 9, wherein a number of bits decoded by each sub-decoder is equal to a size of the codeword divided by a total number of sub-decoders.

12. The apparatus of claim 9, wherein all sub-decoders can begin decoding simultaneously.

13. The apparatus of claim 9, wherein one or more sub-decoders can begin decoding later than other sub-decoders.

14. The apparatus of claim 9, wherein the sub-decoders are of two.

15. The apparatus of claim 9, wherein the sub-decoders are further configured to exchange partial parity check bits with the two adjacent sub-decoders.

16. The apparatus of claim 9, wherein each of the sub-decoders comprises a plurality of variable nodes and a plurality of check nodes and wherein each of the sub-decoders is further configured to exchange a minimum of an absolute value of variable node to check node messages in one sub-decoder that all go to a same check node.

17. A method for decoding a low-density parity-check (LDPC) codeword comprising:
dividing an LDPC codeword into a plurality of exclusive subsets;
distributing each subset to one of a plurality of sub-decoders, wherein the plurality of sub-decoders are configured as an ordered chain of sub-decoders, and wherein each of the sub-decoders is one of two or more types and each interior sub-decoder is between and communicably coupled to each of two adjacent sub-decoders and each of the two adjacent sub-decoders are of a type different from the sub-decoder between them; and
decoding, in each sub-decoder, the associated subset of the LDPC codeword, wherein the decoding includes receiving information from two adjacent sub-decoders.

18. The method of claim 17, wherein the decoding includes sending information to two adjacent sub-decoders.

19. The method of claim 17, wherein the received information includes partial parity check bits.

20. The method of claim 18, wherein the sent information includes partial parity check bits.
